(19) United States
(12) Patent Application Publication
(10) Pub. No.: US 2025/0111109 A1
(43) Pub. Date: Apr. 3, 2025

(54) GENERATING MOTION TOKENS FOR SIMULATING TRAFFIC USING MACHINE LEARNING MODELS

(71) Applicant: NVIDIA Corporation, Santa Clara, CA (US)

(72) Inventors: Jonah PHILION, Toronto (CA); Sanja FIDLER, Toronto (CA); Jason PENG, Vancouver (CA)

(73) Assignee: NVIDIA Corporation, Santa Clara, CA (US)

(21) Appl. No.: 18/664,597

(22) Filed: May 15, 2024

Related U.S. Application Data
(60) Provisional application No. 63/586,347, filed on Sep. 28, 2023.

(51) Int. Cl. G06F 30/27

(52) U.S. Cl. CPC G06F 30/27

(57) ABSTRACT

In various examples, systems and methods are disclosed relating to generating tokens for traffic modeling. One or more circuits can identify trajectories in a dataset, and generate actions from the identified trajectories. The one or more circuits can generate, based at least on the plurality of actions and at least one trajectory of the plurality of trajectories, a set of tokens representing actions to generate trajectories of one or more agents in a simulation. The one or more circuits may update a transformer model to generate simulated actions for simulated agents based at least on tokens generated from the trajectories in the dataset.

### CROSS-REFERENCE TO RELATED APPLICATIONS

This application claims the benefit of and priority to U.S. Provisional Patent Application No. 63/586,347, filed Sep. 28, 2023, the contents of which is incorporated herein by reference in its entirety for all purposes.

### BACKGROUND

Autonomous vehicle systems utilize machine artificial intelligence models to navigate environments. In particular, artificial intelligence models may be utilized to predict the behavior of traffic relating to autonomous vehicle systems. However, it is challenging to automatically predict behavior of several actors in complex environments.

### SUMMARY

Embodiments of the present disclosure relate to systems and methods for traffic modelling using transformer-based artificial intelligence models. The present disclosure provides techniques for tokenizing the motion of dynamic agents (e.g., pedestrians, vehicles, bicycles), and training/updating artificial intelligence models (e.g., transformer models) to simulate/predict traffic movements of different agents over time. Traditional approaches to traffic modeling involve using machine-learning models such as conditional variational autoencoders (VAEs) or generative adversarial networks (GANs), or beam-searching in connection with discrete actions, to simulate movement of agents. However, conventional approaches to traffic modeling suffer from a lack of realism and poor scalability, resulting in subpar simulation performance.

The systems and methods of the present solution can use transformer-based models to predict a fixed number of possible actions that can be performed by a given actor in a single timestep of a traffic simulation, without being subject to the computational shortcomings of conventional solutions. The tokens can represent a motion “vocabulary,” which can be used to model sequences of actions (e.g., a trajectory) for different types of agents in the simulation. Simulating agents using the techniques described herein can provide for scalable, realistic movements that are not possible using conventional machine-learning models.

At least one aspect relates to a processor. The processor can include one or more circuits. The one or more circuits can identify a plurality of trajectories in a dataset. The one or more circuits can generate a plurality of actions based at least on the plurality of trajectories in the dataset. The one or more circuits can generate, based at least on the plurality of actions and at least one trajectory of the plurality of trajectories, a set of tokens representing actions to generate trajectories of one or more agents in a simulation.

In some implementations, the one or more circuits can select a first action for the set of tokens from the plurality of actions. In some implementations, the one or more circuits can filter the plurality of actions based at least on the first action and a threshold distance. In some implementations, each action in the plurality of actions comprises a change in position and a change in heading. In some implementations, the one or more circuits can generate a plurality of candidate sets of tokens based at least on the plurality of actions. In some implementations, the one or more circuits can evaluate each of the plurality of candidate sets of tokens based at least on the at least one trajectory. In some implementations, the one or more circuits can select the set of tokens from the plurality of candidate sets of tokens based at least on the evaluation.

In some implementations, the one or more circuits can evaluate each candidate set of the plurality of candidate sets of tokens by generating a tokenized trajectory based at least on the candidate set and the at least one trajectory. In some implementations, the one or more circuits can evaluate each candidate set of the plurality of candidate sets of tokens by determining an error between the tokenized trajectory and the at least one trajectory.

In some implementations, the one or more circuits can determine the error based at least on respective bounding boxes surrounding (e.g., each of) the tokenized trajectory and the at least one trajectory. In some implementations, the one or more circuits can update a transformer model using the set of tokens. In some implementations, the one or more circuits can update the transformer model further based at least on map data.

At least one other aspect is related to a processor. The processor can include one or more circuits. The one or more circuits can identify a plurality of trajectories in a dataset. The one or more circuits can generate a plurality of tokenized trajectories based at least on the plurality of trajectories and a set of tokens representing actions to be performed at a given timestep along the plurality of trajectories. The one or more circuits can update a transformer model to generate a simulated action for a simulated agent based at least on the plurality of tokenized trajectories.

In some implementations, the one or more circuits can update the transformer model based at least on map data. In some implementations, the map data comprises one or more map objects. In some implementations, the transformer model comprises an encoder-decoder architecture. In some implementations, generating the plurality of tokenized trajectories comprises identifying a respective token from the set of tokens for each timestep of the plurality of trajectories.

In some implementations, the transformer model is updated to generate, in an output data structure, a respective simulated action for each of a plurality of simulated agents. In some implementations, the transformer model is updated to receive an initial state of the simulated agent as input, the initial state comprising one or more of a length, a width, an initial position, an initial heading, or an object class of the simulated agent. In some implementations, the object class comprises one of a pedestrian, a vehicle, or a cyclist.

Yet another aspect of the present disclosure is related to a method. The method can include identifying, using one or more processors, a plurality of trajectories in a dataset. The method can include generating, using the one or more processors, a plurality of actions based at least on the plurality of trajectories in the dataset. The method can include generating, using the one or more processors, based at least on the plurality of actions and at least one trajectory of the plurality of trajectories, a set of tokens representing actions to generate trajectories of one or more agents in a simulation.

In some implementations, the method can include selecting, using the one or more processors, a first action for the set of tokens from the plurality of actions. In some implementations, the method can include filtering, using the one or more processors, the plurality of actions based at least on the first action and a threshold distance. In some implementations, each action in the plurality of actions comprises a change in position and a change in heading.

In some implementations, the method can include generating, using the one or more processors, a plurality of candidate sets of tokens based at least on the plurality of actions. In some implementations, the method can include evaluating, using the one or more processors, each of the plurality of candidate sets of tokens based at least on the at least one trajectory. In some implementations, the method can include selecting, using the one or more processors, the set of tokens from the plurality of candidate sets of tokens based at least on the evaluation.

The processors, systems, and/or methods described herein can be implemented by or included in at least one of a system associated with an autonomous or semi-autonomous machine (e.g., an in-vehicle infotainment system); a system for performing simulation operations; a system for performing digital twin operations; a system for performing light transport simulation; a system for performing collaborative content creation for 3D assets; a system for performing deep learning operations; a system implemented using an edge device; a system implemented using a robot; a system for generating or presenting virtual reality (VR) content, augmented reality (AR) content, and/or mixed reality (MR) content; a system for performing conversational AI operations; a system for performing generative AI operations; a system for performing one or more operations using a language model such as a large language model (LLM) or a vision language model (VLM), a system for generating synthetic data; a system incorporating one or more virtual machines (VMs); a system implemented at least partially in a data center; or a system implemented at least partially using cloud computing resources.

### BRIEF DESCRIPTION OF THE DRAWINGS

The present systems and methods for controllable trajectory generation using neural network models are described in detail below with reference to the attached drawing figures, wherein:

FIG. 1 is a block diagram of an example system that implements generating tokens for traffic modeling for training/updating transformer models, in accordance with some embodiments of the present disclosure;

FIG. 2A illustrates example diagrams showing how tokens can be selected to closely model agent actions based at least on stored trajectories, in accordance with some embodiments of the present disclosure;

FIG. 2B illustrates example plots showing representations of tokens generated to model agent actions using the techniques shown in FIG. 2A, in accordance with some embodiments of the present disclosure;

FIG. 3 is a block diagram of an example transformer model used to generate actions for simulated agents, in accordance with some embodiments of the present disclosure;

FIG. 4 depicts example plots showing trajectories of agents in a simulation generated according to the techniques described herein, in accordance with some embodiments of the present disclosure;

FIG. 5 is a flow diagram of an example of a method for generating tokens for traffic modeling for training/updating transformer models, in accordance with some embodiments of the present disclosure;

FIG. 6 is a block diagram of an example content streaming system suitable for use in implementing some embodiments of the present disclosure;

FIG. 7 is a block diagram of an example computing device suitable for use in implementing some embodiments of the present disclosure; and

FIG. 8 is a block diagram of an example data center suitable for use in implementing some embodiments of the present disclosure.

### DETAILED DESCRIPTION

This disclosure relates to systems and methods for implementing tokenized traffic modeling using a transformer model. Traditional approaches to traffic modeling involve using machine-learning models such as conditional variational autoencoders (VAEs) or generative adversarial networks (GANs), or beam-searching in connection with discrete actions, to simulate movement of agents (e.g., vehicles, cyclists, pedestrians, etc.). However, conventional approaches to traffic modeling suffer from a lack of realism and poor scalability, resulting in subpar simulation performance. For example, approaches relying on VAEs are not optimized on log-likelihood, and therefore suffer from a lack of realism, while beam-search approaches lack scalability and suffer from poor performance as the number of agents being simulated increases.

The systems and methods described herein provide techniques for tokenized traffic modeling, in which trajectories are “tokenized” to train/update a transformer model to produce possible new positions and/or headings for multiple simulated agents. The transformer model, which may include an encoder-decoder transformer model (e.g., comprising one or more encoders in communication with at least one decoder), can be trained/updated to simulate traffic movements of different agents over time. The tokens generated according to the present techniques may include a fixed number of possible actions can be performed by a given actor in a single timestep of a traffic simulation. The tokens can represent a motion “vocabulary” which can be used to model sequences of actions (e.g., a trajectory) for different types of agents in the simulation.

The tokens used to represent agent movement may be selected from a large number of trajectory changes (e.g., changes in position and heading) over time. To select a set of tokens that can be used to best model a diverse set of trajectories, a large corpus of raw trajectories can be sampled to generate candidate sets of tokens. Each candidate set of tokens may be generated by first randomly selecting a token from the corpus, and then filtering the corpus to remove other possible actions that are sufficiently similar to (e.g., within a threshold distance of) the first selected action. This process can be repeated until a predetermined set of tokens have been selected. Multiple candidate sets of tokens can be generated and evaluated to select the set of tokens that best models the motion of an agent over the raw trajectories in the dataset. Different sets of tokens may be generated to represent actions taken by different types of agents, including tokens specific to vehicles, cyclists, or pedestrians, among others.

Once the set of tokens has been generated, sequences of those tokens for multiple timesteps may be used to construct simulated trajectories for simulated agents. The transformer model can be trained/updated using tokenized trajectories to generate the next action for each agent in the simulation for each time step, ultimately generating a trajectory for each agent over time. The transformer model can receive both information relating to each agent and information defining the environment (or map) within which the agents are navigating to generate the output actions. The use of a transformer architecture enables scalable simulations for large numbers of agents while preserving realism by training/updating using exact log-likelihood.

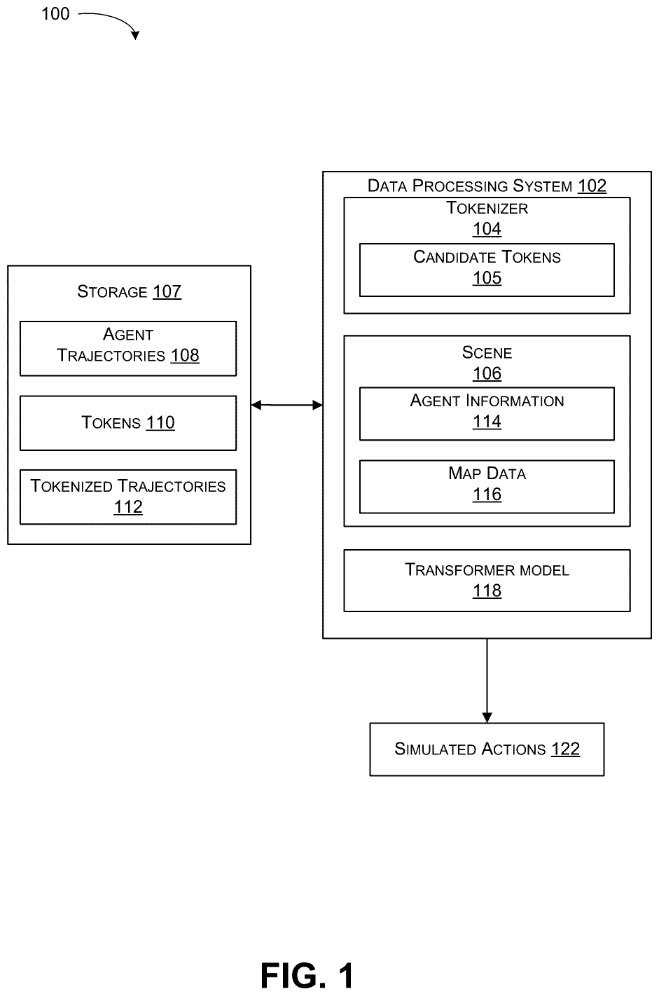

FIG. 1 is an example computing environment including a system 100, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory. The system 100 can include any function, model (e.g., machine-learning model), operation, routine, logic, or instructions to perform functions such as generating tokens or training/updating and/or executing transformer models as described herein.

The system 100 is shown as including the data processing system 102 and the storage 107. The data processing system 102 can access the storage 107 to retrieve agent trajectories 108, which may be utilized to generate corresponding tokens 110 and/or candidate tokens 105 for modelling agent actions in a scene 106 (e.g., a simulated scene). The storage 107 may be an external server, distributed storage/computing environment (e.g., a cloud storage system), or any other type of storage device or system that is in communication with the data processing system 102. Although shown as external to the data processing system 102, it should be understood that the storage 107 may form a part of, or may otherwise be internal to, the data processing system 102.

The data processing system 102 may generate a set of tokens 110 that represent a discrete set of actions that can be performed by an agent in the simulation 106. The actions may include one or more of a change in position and a change in heading. Actions represented by the tokens 110 are used as a “vocabulary” to represent any possible action that an agent may perform during a single timestep. The tokens 110 may be used in connection with a machine-learning model, such as the transformer model 112, to autoregressively model the behavior of multiple agents in a scene 106 over time, in which agents performing an action (e.g., corresponding to a respective token 110) at each time step.

Prior to describing techniques for generating the tokens 110 to simulate agent actions using a transformer model 112, a brief overview of the simulation environment to model traffic behavior is provided. A simulation may include a simulation of a scene 106, in which the positions and headings of agents are simulated to navigate a simulated environment. The scene 106 may represent the state of a traffic simulation and environment in which one or more agents are navigated. As shown, the scene 106 can include agent information 108 (e.g., length, width, height, and class of the one or more agents) and/or map data 110. As used herein, initialization information for a scene 106 is denoted by c. The agent information 108 may include state information at each of a sequence of timesteps in the simulation, which can be denoted by sₜⁱ=(xₜⁱ, yₜⁱ, hₜⁱ), where (x, y) can represent the location of the center of a bounding box of the agent and h can represent the heading of the agent in the scene 106.

When simulating a scene, for a simulation of T timesteps, a distribution of interest traffic modeling can be represented as: p(s₁¹, . . . , s₁^{N}, s₂¹, . . . , s₂^{N}, . . . , s_{T}¹, . . . , s_{T}^{N}|c). Samples from said distribution may sometimes be referred to herein as rollouts. When modeling traffic, one goal is to sample realistic rollouts from this distribution under the restriction that at each timestep, a black-box autonomous vehicle (AV) system chooses a state for a subset of the agents. This interaction model imposes the following factorization of the joint likelihood expressed in the following equation:

$$p ( {s}_{1}^{1} , … , {s}_{1}^{N} , {s}_{2}^{1} , … , {s}_{2}^{N} , … , {s}_{T}^{1} , … , {s}_{T}^{N} \vert c ) = {\prod }_{1 \leq t \leq T} p ( {s}_{1}^{1 … {N}_{0}} \vert c , {s}_{1 … t - 1} ) p ( {s}_{1}^{{N}_{0} + 1 … N} \vert c , {s}_{1 … t - 1} , {s}_{t}^{1 … {N}_{0}} )$$

In the above equation, s_{1 . . . t-1}≡{s₁¹, s₁², . . . sₜ₋₁^{N}} can be the set of all states for all agents prior to timestep t, sₜ^{1 . . . N}^{₀}≡{s₁¹, s₁², . . . sₜ₋₁^{N}} can be the set of states for all agents 1 through N at time t, and in this example the agents that are modeled according to the techniques described herein can include indices 1 . . . . N₀. The factorization shown in the above equation shows that a model can be used to sample an agent's next state conditional on all states sampled in previous timesteps as well as any states already sampled at the current timestep.

Although real-world driving environments involve independent actors, there are multiple reasons that intra-timestep dependence might still exist in log data (e.g., the agent trajectories 108, as described in further detail herein). For example, driving logs can be recorded at discrete timesteps, and therefore any interaction in the real-world that occurs between any two timesteps gives the appearance of coordinated behavior in log data. Additionally, information that is not recorded in log data, such as eye contact or turn signals, may lead to intra-timestep dependence. Further, in some implementations, log data storing agent trajectories can be stored in chunks, which can result in intra-timestep dependence if there were events before the start of the log data that result in coordination during the recorded scenario. While these effects are in general weak, the techniques described herein can be used to explicitly model intra-timestep interaction.

The data processing system 102 can model traffic behavior by performing operations to discretize, or tokenize, driving actions using driving log data. The tokens 110 generated according to the techniques described herein can be selected such that they model the conditional distributions required by the factorization of the joint likelihood provided herein. The data processing system 102 can perform a tokenization process using the tokenizer 104 to create a set of candidate tokens 105 from agent trajectories 108. The set of candidate tokens 105 can be evaluated to determine whether the set of candidate tokens 105 is to be used as the set of tokens 110. The tokens 110 can be used to model the distribution of changes in position and heading at a given time step (e.g., a change in state of an agent in a scene 106, sometimes referred to herein as “actions”) across a diverse set of agent trajectories. Each set of candidate tokens 105, and the tokens 110, may have a fixed size (sometimes referred to herein as a “vocabulary size”).

The tokenizer 104 can generate the set of tokens 110 and candidate tokens 105 as a fixed set of state-to-state transitions, or actions. Each generated set of candidate tokens 105 can be evaluated against several agent trajectories 108 to select the set of candidate tokens 105 that best generates corresponding agent trajectories 108, which can be stored as the set of tokens 110. The set of tokens 110 therefore represents a set of actions that represents a motion “vocabulary” for a particular type of agent, with which the data processing system 102 can best model agent motion using the techniques described herein.

The agent trajectories 108 can be any type of log data that indicates information about how an agent, such as a vehicle, bicycle, or pedestrian, navigates an environment. An agent trajectory 108 can include time-series data indicating changes in position and a change heading over time as the agent navigated an environment. Each point of an agent trajectory 108 can include a heading and a position for the agent to which the agent corresponds at a particular moment in time. The agent trajectory 108 may therefore be stored as a time-series list of position values and heading values. In some implementations, the position values of the agents in the agent trajectories 108 are stored as sets of Cartesian coordinates (e.g., x, y coordinates). The coordinates may be relative coordinates (e.g., relative to the first position in the trajectory), or may be relative to another frame of reference (e.g., global positioning system (GPS) coordinates, etc.). In some implementations, the heading values may be relative to a predetermined frame of reference or may be relative to the previous heading in a previous point in the time-series data. In some implementations, the state (e.g., the position and heading) of each agent in an agent trajectory 108 includes a timestamp or index value that defines a relative time from the start of the trajectory to the state represented by the timestamp or index value.

In some implementations, each agent trajectory 108 can include information about the type of agent for which the trajectory is defined. For example, an agent trajectory 108 may indicate that the trajectory was traversed by a vehicle, a pedestrian, or a bicycle based at least on metadata associated with a corresponding agent trajectory 108. Additional metadata for the agent can also be included in the agent trajectories 108. Examples for different metadata that may be included in the agent trajectories 108 include, but is not limited to, dimensions (e.g., length, width, height) of the agent, a type of vehicle represented by the agent (if any), or a label or classification for the trajectory (e.g., indicating a type of trajectory traversed by the agent), among others.

To sample a set of candidate tokens 105 with which to generate the set of tokens 110 to model a diverse set of agent trajectories 108, the tokenizer 104 can retrieve a set of state transitions, or actions (e.g., changes in position and/or heading between two timesteps), from a number of agent trajectories 108, sample one of them, and perform a filtering process for any transitions that are within the epsilon distance under a corner distance metric. The algorithm used to select a set of candidate tokens 105 is provided below:

Algorithm 1: Sample a target number N candidate tokens 105
(e.g., candidate template actions), where the distance d(x₀,
x) measures the average corner distance between a box of length 1
meter and width 1 meter with state x₀ vs. state x.

```
procedure SampleKDisks(X, N, ϵ)
  x₀~X
  X ← {x ∈ X | d(x₀, x) > ϵ}
  S ← S ∪ {x₀}
return S
```

In the above algorithm, the number N can represent the vocabulary size of the set of candidate tokens 105, with which the data processing system 102 can generate corresponding agent trajectories. Example vocabulary sizes may include but are not limited to 128 tokens, 256 tokens, 384 tokens, or 512 tokens, among others.

The data processing system 102 can generate multiple sets of candidate tokens 105, each of which may be evaluated by tokenizing a diverse set of agent trajectories 108. Each agent trajectory 108 can be evaluated by first tokenizing the agent trajectory 108 using a set of candidate tokens 108 that is to be evaluated. The data processing system 102 can evaluate the set of candidate tokens by determining the L2 error between the actual agent trajectory 108 and the tokenized trajectory generated using the set of candidate tokens 105. This may be referred to as the “full tokenization L2 error,” and can be calculated across several agent trajectories 108 using these techniques. The L2 error can be calculated based at least on respective bounding boxes surrounding each of the tokenized trajectory 112 and the corresponding agent trajectory 108. Multiple sets of candidate tokens 105 can be sampled using the techniques described herein, and subsequently evaluated to identify a set of candidate tokens 105 that best reproduces a diverse set of agent trajectories 108 in a test set of agent trajectories 108. This set of candidate tokens 105 can be stored as the tokens 110, which can be utilized in connection with the modelling techniques described herein to simulate motion of various agents in a scene 106.

To tokenize an agent trajectory 108 using the set of tokens 110 (or a set of candidate tokens 105), the tokenizer 104 can access an agent trajectory 108 and can retrieve an initial state (s₀), which includes an initial heading and an initial position, from the agent trajectory 108. The tokenizer 104 can also access metadata from the agent, including the length/and the width w of the agent. For the purposes of describing the operations of the tokenizer, the value s is used to represent the next state in the accessed agent trajectory 108 for which a token 110 is to be generated by the tokenizer 102.

To do so, the tokenizer 104 can select a corresponding token (e.g., a candidate token 105, a token 110) that best models the change in position and heading from the initial state so to the next state s. The candidate tokens 105 (or tokens 110) from which the token is selected may be referenced as V={sᵢ}, each of which represent a change in position and/or heading in the coordinate frame of the most recent state (in this example, s₀). The tokenizer 104 can generate or otherwise retrieve tokens upon identifying a state (e.g., s₀) in an agent trajectory 108 for tokenization. For the following discussion, the notation at E N is used herein to indicate the index representation of token template sᵢ, and ŝ is used herein to represent the raw representation (e.g., the token 110, candidate token 105) of the tokenized state s.

Based at least on the above representations, the token selection process for tokenizing an agent trajectory 108 performed by the tokenizer 104 can be represented by the following equation:

$$f ( {s}_{0} , s ) = {a}_{i *} = arg min {d}_{l , w} ( {s}_{i} , local ( {s}_{0} , s ) )$$

where d_{l,w}(s₀, s₁) is the average of the L2 distances between ordered corners of bounding boxes defined by s₀ and s₁, “local” converts s to the local frame of s₀. The corner distance metric is referred to elsewhere herein by d_{l,w}(⋅,⋅). To tokenize an entire agent trajectory 108, the tokenizer 104 converts each state s to its tokenized counterpart § iteratively for each state in agent trajectory 108, using tokenized states as the base state so each next tokenization step. The tokenizer 104 can store the tokenized agent trajectory 108 of length T (e.g., having T positions and headings in time-series) as a tokenized trajectory that includes a tokenized initial state followed by a T−1 indices.

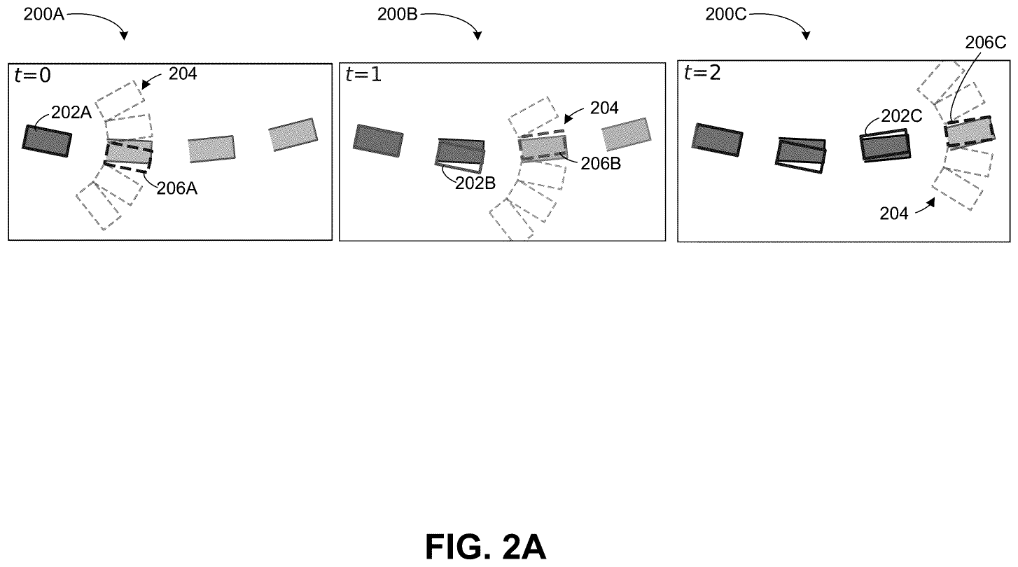

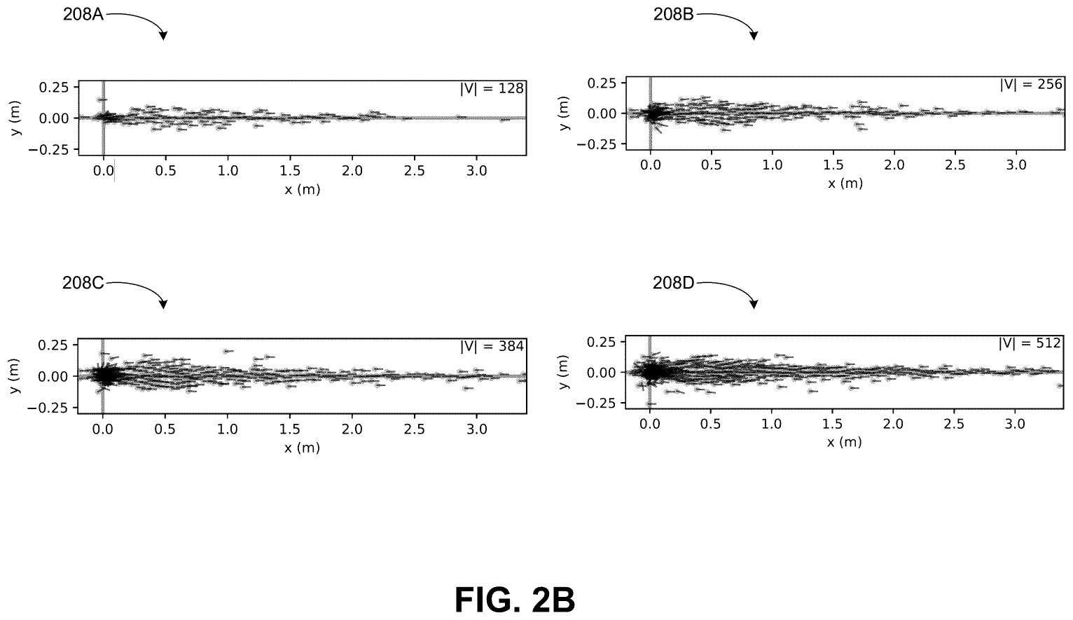

Referring to FIG. 2A, illustrated are example diagrams showing how tokens can be selected to closely model agent actions to tokenize stored trajectories (e.g., the agent trajectories 108), in accordance with some embodiments of the present disclosure. In each step 200A, 200B, and 200C, an example trajectory indicated by the shaded rectangles is shown, with darker shading representing the current and preceding timesteps for each timestep represented in the steps 200A, 200B, and 200C. As shown at the initial timestep t=0 at step 200A, the initial state so is used as the initial token 202A, and a token 206A is selected from the set of tokens 204 (which may be similar to the set of tokens 110 of FIG. 1) with minimum corner distance to the bounding box represented by the next state (which may be determined based at least on the position, heading, and agent information indicated in the agent trajectory 108 of FIG. 1). Example plots showing sets of tokens with which the agents can be modeled are shown in FIG. 2B. The selected token 206A is selected to indicate an action taken by the agent at timestep t=0 to reach the state in the agent trajectory at the next timestep (e.g., t=1).

Although the foregoing techniques have been described as being performed for a single agent, it should be understood that the data processing system 105 can generate a corresponding set of tokens 110 for each type, class, or instance of agent that is to be simulated according to the techniques described herein. For example, the data processing system 102 may access and process agent trajectories for pedestrians, bicycles, automobiles (e.g., trucks, sedans, etc.) with different attributes or properties, to generate corresponding vocabularies for each type of agent. A set of tokens 110 generated for a type of agent may therefore be stored in association with an identifier of the type of agent.

This process is iteratively repeated for each time step in steps 200B and 200C. As shown, at step 200B, the state represented by the selected token 206A is used as the initial state 202B for timestep t=1, and a token 206B is selected from the set of tokens 204 that represents the action taken by the agent at timestep t=1 to most closely resemble the next state indicated in the agent trajectory. This process is repeated in step 200C, in which the selected token 206B from t=1 is used as the initial state 202C for timestep t=2, and a token 206C is selected from the set of tokens 204 that represents the action taken by the agent at timestep t=1 to most closely resemble the next state indicated in the agent trajectory. This process is repeated iteratively for each timestep indicated in the agent trajectory until corresponding tokens have been selected for each timestep.

Referring to FIG. 2B, illustrated are example plots showing representations of tokens (e.g., tokens 110) generated to model agent trajectories using the techniques shown in FIG. 2A, in accordance with some embodiments of the present disclosure. As shown in FIG. 2B, the plot 208A shows a set of tokens having a vocabulary size of 128, which may be utilized to model agent motion in one or more scenes. As shown, agent motions can be modeled using different vocabulary size, including a vocabulary size of 256 as shown in the plot 208B, a vocabulary size of 384 as shown in the plot 208C, and a vocabulary size of 512 as shown in the plot 208D. In each plot, each point represents a respective token in the vocabulary for each agent. The position of a point in each plot can represent a change in forward, backward, and lateral position represented by the token, and the angle of the ray extending from each point can represent a change in heading represented by the token.

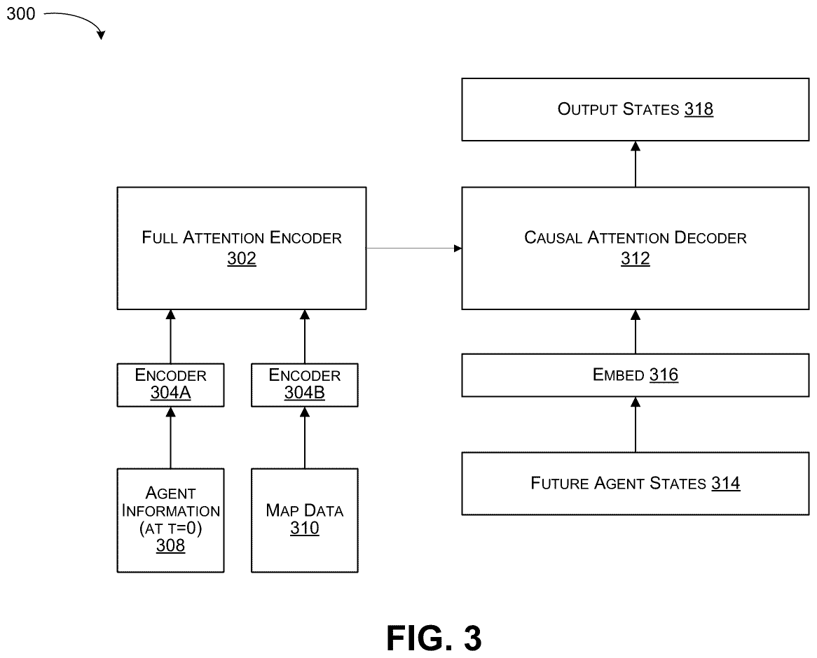

Referring back to FIG. 1, once the tokens 110 are generated (e.g., and corresponding actions associated therewith), the data processing system 102 can store the tokens 110 in the storage 107, as shown, and utilize the tokens 110 to simulation motion for one or more agents in a scene 106. To simulate the motion of one or more agents in the scene 106, the data processing system 102 can train a transformer model 118 to generate simulated actions (represented by corresponding tokens 110) for the one or more agents. The transformer model 118 may include an encoder-decoder structure. An example implementation of the transformer model 118 is described in connection with FIG. 3.

The transformer model 118 can be trained to receive agent information 114 and map data 116 of the scene 106 to simulate corresponding agents in the scene 106. The agent information 114 may include initial state data of any agents present in the scene 106. The agent information 114 can include a length, width, height, initial position, initial heading, and/or class of each agent in the scene 106. The agent information 114 may be stored as part of a set of initial conditions for a scene 106 that is to be simulated. In some implementations, the agent information 114 may be received in a request to simulate a particular scene 106 or may be retrieved in response to a similar request or input provided to the data processing system 102.

The map data 116 can include a representation of an environment that is simulated as part of the scene 106. The map data 116 can include any type of data that can be used to represent various obstacles or navigation areas in which simulated agents can navigate. In some implementations, the map data 116 may include data structures that represent a map as a collection of “map objects.” In such implementations, a map object can include a variable-length polyline representing a lane, sidewalk, crosswalk, or other navigable space. The map objects may include obstacles, or objects and regions through which agents cannot navigate in the scene 106. The map data 116 may represent a two-dimensional (2D) or three-dimensional (3D) environment and map objects.

The transformer model 118 may include one or more layers, such as one or more multi-layer perceptron (MLP) layers, which generate corresponding embeddings from input agent information 114 and map data 116. The transformer model 118 may be trained/updated such that it is not permutation equivariant to agents but is permutation invariant to the ordering of map objects. To train the transformer model 118, the data processing system can access the agent trajectories 108 and utilize the set of tokens 110 generated according to the techniques described herein to generate a set of tokenized trajectories 112, which can be used as training data.

The tokenized trajectories 112 may be generated using the tokenizer 104 to implement the iterative tokenization process described in connection with FIG. 2A over a set of agent trajectories 108 that are designated for use as training data. The tokenized trajectories 112 may therefore include a sequence of state changes represented by respective tokens 110 in a sequence. In some implementations, tokenized trajectories 112 may be generated for agents that produced the agent trajectories 108 in the same environment (e.g., proximate to one another), such that the set of tokenized trajectories 112 can model intra-timestep motion of multiple agents. In some implementations, the tokenized trajectories 112 can be stored in connection with training map data, which indicates objects in the environment within which the corresponding agent trajectories 108 designated as training data were generated. The tokenized trajectories 112, once generated by the data processing system 102, can be stored in the storage 107, as shown.

The data processing system 102 can train/update the transformer model using the tokenized trajectories 108 to generate the next simulated action for each agent navigating a given scene 106. For example, the data processing system 102 may execute an iterative training/updating process that includes encoding each tokenized trajectory 112 (and corresponding map data) used as input sequence(s) to the transformer model 118 and updating the weights of the transformer model 118 using backpropagation or other types of optimization algorithms. The data processing system 102 may perform multiple training/updating iterations, each of which may include calculating a corresponding loss between an expected output of the transformer model 118 and an actual output of the transformer model 118. Various hyperparameters for the transformer model 118, and for the training process, may be provided to the data processing system 102 in a request to train the transformer model or from a stored configuration for training the transformer model 118.

In some implementations, the data processing system 102 can train/update the transformer model 118 using regularization techniques. For example, in some implementations, the data processing system 102 can train/update the transformer model 118 using teacher forcing, where the transformer model 118 is trained on the tokenized trajectories 112 of the ground-truth agent trajectories 108. Additionally, to circumvent the fact that the transformer model 118 does not necessarily model the ground-truth distribution perfectly, the data processing system 102 can perform noising on the input tokens 110 provided as input to the transformer model 118. To do so, the data processing system 102 can, when tokenizing the input agent trajectories 108 for training/updating the transformer model 118, sample the token 110 from the following distribution rather than choosing the token 110 with minimum corner distance to the ground-truth state as described herein:

$${a}_{i} ∼ {softmax}_{i} ( nucleus ( \frac{d ( {s}_{i} , s )}{σ} , {p}_{top} )$$

In such implementations, the data processing system 102 can use the distance between the ground-truth raw state and the tokens 110 as logics of a categorical distribution with temperature σ, and apply nucleus sampling to generate sequences of motion tokens. When σ=0, this approach recovers the tokenization strategy described herein above. For example, if two tokens are equidistance from the ground-truth under the average corner distance metric, this approach will sample one of the two tokens with equal probability during training/updating of the transformer model 118. The data processing system 102 can retain and utilize the minimum-distance token 110 index as the ground-truth target even when noising the input sequence. Training/updating the transformer model 118 using regularization can make the transformer model 118 more robust to errors during testing processes. These approaches can be used to improve the performance in circumstances where all agents are controlled via outputs of the transformer model 118.

Once trained, the data processing system 102 can execute/use/apply the transformer model 118 to generate one or more simulated actions 122 of corresponding agents in the scene 106. The simulated actions 122 can be represented by tokens 110 output from the transformer model 118 given a set of initial input conditions (e.g., agent information 114, map data 116, etc.). The initial input conditions may include state data for one or more agents and/or map data 118 for one or multiple sequential timesteps. Said initial input conditions may be referred to herein as “seed” data. Additional random values, which may be generated by the data processing system 102 using a suitable random number generation technique, may be provided as input to the transformer model 118 to facilitate randomness in generation of the simulated actions 122.

Because the simulated actions 122 are represented by the tokens 110, each simulated action 122 corresponds to a respective change in position and/or heading for a particular agent in the scene 106. Simulated actions 122 for all agents in the scene 106, once generated by the transformer model based at least on the initial input data (e.g., the agent information 114, the map data 116) can be concatenated or otherwise added to the initial input data in sequence, which can then be provided as input to the transformer model 118. The data processing system 102 can then execute the transformer model 118 to generate the next set of simulated actions 122 for the agents in the scene 106 in the next timestep. This process can be repeated for any number of timesteps 122 (up to the context length of the transformer model 118) to simulate motion of the agents in the scene 106 over time. An example architecture of a transformer model 118 is described in connection with FIG. 3.

It should be understood that the transformer model 118 described herein can be trained/updated to generate simulated actions 122 for all agents in a scene 106 or a subset of agents in a scene 106, in some implementations. For example, in a full control contest, the transformer model 118 can be executed to produce simulated actions for all agents in a scene 106, such that the transformer model 118 is executed to generate the next simulated action 122 for all agents in a scene given only the initial state information of said agents, without any external control or route specification provided as input. In a partial control scenario, the transformer model 118 can be executed to produce simulated actions 122 for a subset of the agents in the scene 106, while the trajectories of other agents are predetermined or otherwise controlled according to external input. For example, agents that are not simulated based on the outputs of the transformer model 118 may be controlled according to respective data stored in the agent trajectories 108. The transformer model 118 being trained/updated to simulate intra-timestep dependence significantly reduces collision instances compared to conventional traffic modeling techniques.

Referring to FIG. 3, illustrated is a block diagram d of an example transformer model 300 used to generated actions (e.g., simulated actions 122) for simulated agents in a scene (e.g., a scene 106), in accordance with some embodiments of the present disclosure. In this example, the transformer model 300 is shown as having an encoder-decoder architecture, and includes a full attention encoder 302, a causal attention decoder 312. Additionally, the transformer model 300 is shown as including two encoders 304A and 304B. The diagram in FIG. 3 shows a forward pass of data through the transformer model 300 during a training/updating process.

The encoder 304A can include one or more layers of MLPs that are configured to receive initial agent information (e.g., initial state data so, agent information 114, etc.) as input, and produce corresponding encoded embeddings for input to the full attention encoder 302. In some implementations, the encoder 304A can include other types of machine-learning model layers. The embeddings generated by the encoder 304A can include encoded data that represents the agent information 114. The output embeddings generated by the encoder 304A can be encoded on a per-agent basis, and have a size C. Positional embeddings can then be added that encode the agent's order and identity across the sequence of actions. The encoder 304B can include one or more vector encoders, such as a VectorNet encoder having one or more layers, which generates a sequence of embeddings for M map objects (e.g., the map data 116).

The embeddings can be provided as input to the full attention encoder 302. The full attention encoder 302 can include multiple transformer layers that attend to all valid agent and map embeddings (including the positional embeddings) generated using the encoder 304A and 304B. The transformer layers may include multiple attention mechanisms, which compute a weighted sum of its inputs (the output of the previous layer). The attention layers may include self-attention mechanisms and/or multi-head attention mechanisms. In some implementations, the full attention encoder 302 may include one or more feed-forward layers, which may include fully connected neural network layers. As shown, the output of the full attention encoder can be provided as input to the causal attention decoder 312.

The causal attention decoder 312, in this example, can be trained/updated to receive a set of future agent states 314 (sometimes referred to as future agent trajectories) as input, which may be tokenized sequences of agent actions (e.g., the tokenized trajectories 112). During the training/updating process the tokenized trajectories of the future agent states 314 can be flattened according to the same order used to apply positional embeddings to the encoder 304A to get an ordered agent a sequence of agent states a₀⁰a₁⁰ . . . a_{N}^{T}. A start token is prepended to the sequence of agent states and the last token is removed. An embedding table 316 is then used to encode the resulting sequence, and the resulting embeddings can be provided as input to the causal attention decoder 312. The embedding table 316 can be any suitable table that may be used to generate embeddings given an input sequence of agent states.

The causal attention decoder 312 can include one or more transformer layers. In some implementations, a causal mask can be applied during the training/updating process for the transformer model 300. The transformer layers in the causal attention decoder 312 can include one or more self-attention mechanisms, which can weigh the importance of different positions in the input sequence when generating the current output token. Causal masking can be applied to the self-attention mechanism to enforce autoregressive outputs. The causal attention decoder 312 can include one or more linear layers that can decode an output distribution of the transformer layers over the set of tokens (e.g., the tokens 110) for which the transformer model 300 is trained. In some implementations the token embedding matrix can be tied to the weight of the final linear layer. The decoded output distribution of the linear layers is stored as the output states 318. The output states 318 can include a predicted next token in the sequence for each of the agents.

Although the transformer model 300 can be trained to predict the next token in the sequence for each simulated agent, it should be understood that since the embeddings for later tokens attend to the embeddings of earlier tokens, the transformer model 300 optimizes embeddings of agent trajectories that improve the prediction of future motion for all future timesteps across all agents. Because the transformer model 300 receives sequences from multiple agent sequences, the transformer model 300 can be trained/updated to model the intra-timestep relationship between agents.

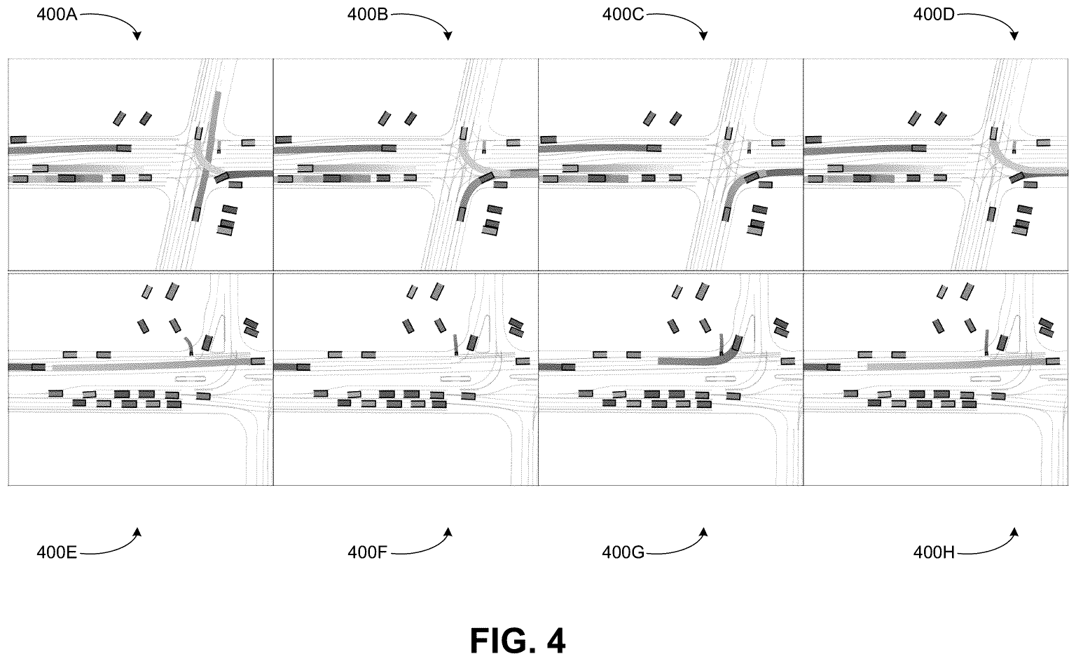

Referring to FIG. 4, depicted are example plots 400A, 400B, 400C, 400D, 400E, 400F, 400G, and 400H showing trajectories of agents in a simulation generated according to the techniques described herein, in accordance with some embodiments of the present disclosure. The diagrams in each row in FIG. 4 each have the same initialization state (e.g., number and class of agents, agent dimensions, agent position, agent heading, map data). The initialization state of each agent in the plots 400A, 400B, 400C, 400D, 400E, 400F, 400G, and 400H is represented by a respective black outline, which also indicates the heading of the agent. In each diagram, simulated trajectories of agents are shown as shaded tracks over the diagram, while map data (e.g., indications of lanes and roads) are represented with shaded lines.

Although certain diagrams show overlapping tracks, it should be understood that the trajectories corresponding thereto do not overlap when time is considered, as there are no collisions between agents resulting from the simulation. As described herein, the trajectories shown in the diagrams of FIG. 4, the transformer model predicts actions defined relative to an agent's current location and heading, and conditions the predictions on map information, actions from previous timesteps, and any actions that have already been selected for other agents within the current timestep. Additionally, as shown, transformer models trained/updated according to the techniques described herein can generate realistic, simulated navigation scenarios given only initial heading and position of agents.

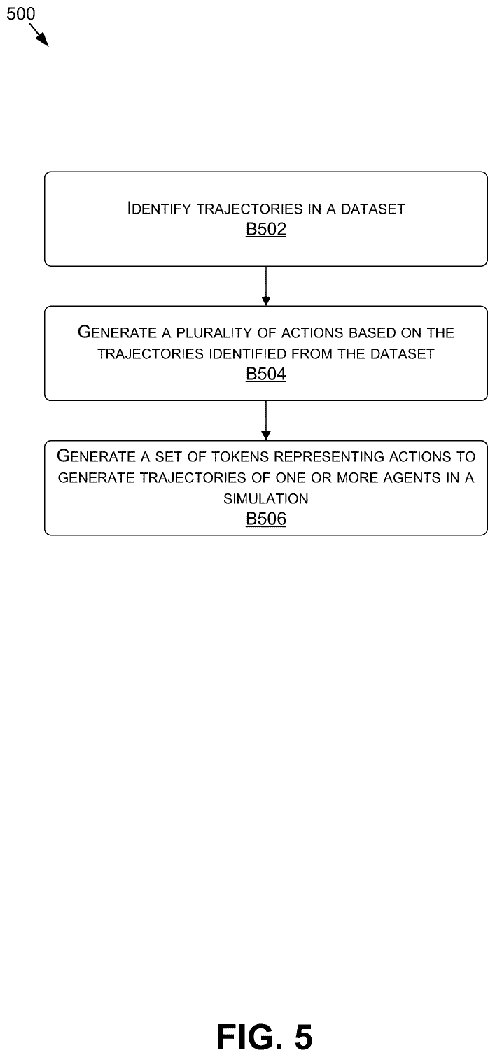

Now referring to FIG. 5, each block of method 500, described herein, comprises a computing process that may be performed using any combination of hardware, firmware, and/or software. For instance, various functions may be carried out by a processor executing instructions stored in memory. The method 500 may also be embodied as computer-usable instructions stored on computer storage media. The method 500 may be provided by a standalone application, a service or hosted service (standalone or in combination with another hosted service), or a plug-in to another product, to name a few. In addition, method 500 is described, by way of example, with respect to the system of FIG. 1, and may be utilized to generate tokens (e.g., tokens 110) for modeling traffic behavior in a simulation, as well as to execute and/or train/update the transformer models described herein (e.g., the transformer model 118 of FIG. 1, the transformer model 300 of FIG. 3, etc.). However, this method 500 may additionally or alternatively be executed by any one system, or any combination of systems, including, but not limited to, those described herein.

FIG. 5 is a flow diagram showing a method 500 for creating fields for generating tokens to model agent motion in a simulation, in accordance with some embodiments of the present disclosure. Various operations of the method 500 can be implemented by the same or different devices or entities at various points in time. For example, one or more first devices may implement operations relating to retrieving, providing, or otherwise aggregating agent trajectories for tokenization, and one or more second devices may implement operations relating to generation of tokens to model the agent trajectories.

The method 500, at block B502, includes identifying one or more trajectories in a dataset (e.g., the agent trajectories 108). The trajectories may correspond to agents navigating one or more environments, and can include ordered sequences of time-series changes in position and/or heading of the respective agent. In some implementations, the position can be coordinates identifying the center of a particular agent at a given timestep, and the heading can be an angle from a predetermined origin that indicates how the relative rotation of the respective agent. As described herein, agents may refer to simulated pedestrians, vehicles, bicycles, or other entities for which motion may be modeled, and may be associated with corresponding metadata. Identifying trajectories for use in generating tokens to model motion of a particular type of agent can include identifying trajectories of entities having the target agent type. For example, if tokens are to be generated to model bicycle motion in a simulation, trajectories corresponding to bicycles can be identified for further processing.

The method 500, at block B504, includes generating a plurality of actions (e.g., the candidate tokens 105) based at least on the trajectories identified in the dataset. To generate the candidate set of actions, operations similar to those described in connection with the tokenizer 104 of FIG. 1 can be performed. For example, Algorithm 1, as described herein, can be utilized to select a candidate vocabulary of candidate tokens, or actions, which can be used to tokenize trajectories of agents and/or simulate actions of agents in a scene (e.g., a scene 106). Each action in the plurality of actions comprises a change in position and a change in heading. To generate the actions, a large number of states changes within the identified agent trajectories can be randomly sampled. One of the actions can be selected (e.g., as a candidate token 105 for a set of candidate tokens 105), and other actions within sampled set of actions can be filtered for any state transitions (actions) that are within a specified epsilon distance under a corner distance metric. This process can be repeated until a candidate set of actions (e.g., a candidate set of tokens 105) of a specified vocabulary size has been generated. Multiple candidate sets of actions can be generated according to these techniques for subsequent evaluation to generate a set of tokens to model agent actions, as described in connection with block B506.

The method 500, at block B506, includes generating, based at least on the plurality of actions and at least one trajectory of the plurality of trajectories, a set of tokens (e.g., the tokens 110) representing actions to generate trajectories of one or more agents in a simulation. To generate a set of tokens 110 for the particular agent type that best models a diverse set of agent trajectories, each of the candidate sets of tokens generated in block B504 can be evaluated by tokenizing one or more raw trajectories of the same agent type (e.g., the agent trajectories 108), and determining a corresponding error between the tokenized trajectory and the full raw trajectory. The error may be, in some implementations, an L2 error. For example, the L2 error may be an average L2 error generated by tokenizing several agent trajectories in a test set of trajectories for use in evaluating the candidate sets of actions. The candidate set of actions having the least error across the testing set of trajectories can be selected as the set of tokens for modeling motion of the agent.

Once the set of tokens for the agent have been generated/selected, a transformer model (e.g., the transformer model 118, the transformer model 300) can be trained/updated using the set of tokens to generated simulation actions (e.g., the simulated actions 122) for a scene given at least a set of initial conditions (e.g., the agent information 114) and map data (e.g., the map data 116). The map data can include one or more map objects, as described herein. The transformer model can be any type of machine-learning model that includes a transformer layer having one or more attention mechanisms. In some implementations, other types of machine-learning models may be utilized, such as recurrent neural networks (RNNs). In some implementations, the transformer model may include an encoder-decoder architecture.

To update/train the transformer model, a set of agent trajectories included in a training dataset can be tokenized according to the techniques described herein. Suitable optimization techniques, including causal masking and backpropagation, can be implemented to train/update the parameters of the transformer model to generate next actions in a sequence of actions for one or more agents in a scene, as described herein.

### Example Content Streaming System

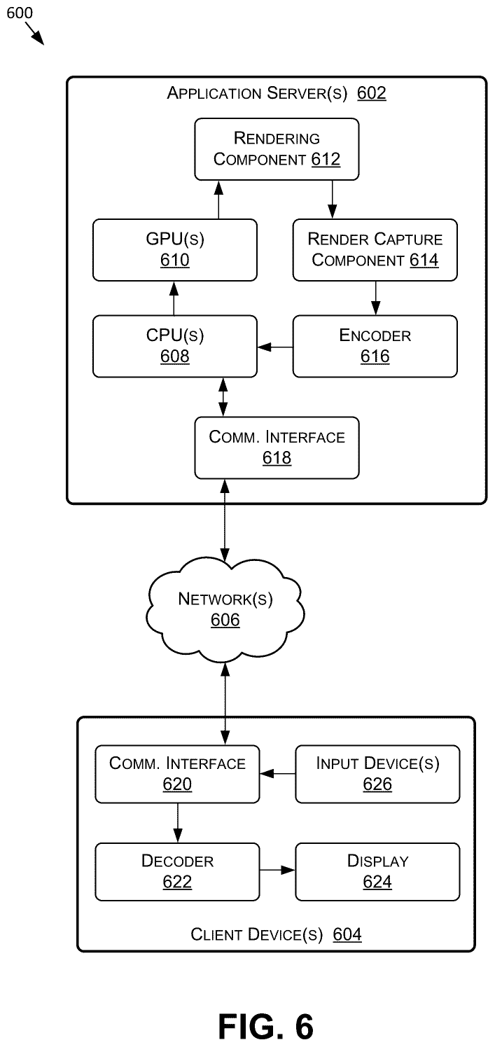

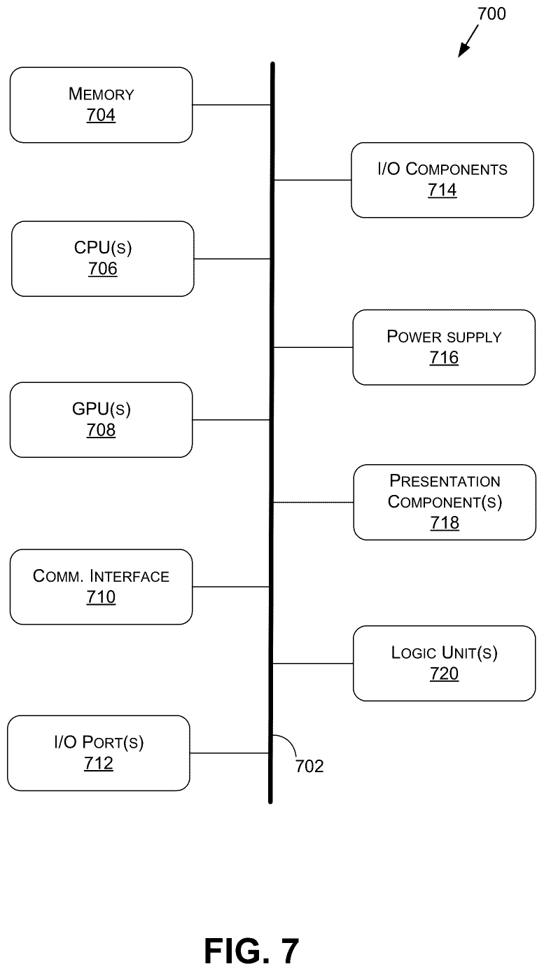

Now referring to FIG. 6, is an example system diagram for a content streaming system 600, in accordance with some embodiments of the present disclosure. FIG. 6 includes application server(s) 602 (which may include similar components, features, and/or functionality to the example computing device 700 of FIG. 7), client device(s) 604 (which may include similar components, features, and/or functionality to the example computing device 700 of FIG. 7), and network(s) 606 (which may be similar to the network(s) described herein). In some embodiments of the present disclosure, the system 600 may be implemented to generate tokens to model agent actions and/or update/train or execute machine-learning models to simulate agent actions, as described herein. The application session may correspond to a game streaming application (e.g., NVIDIA GEFORCE NOW), a remote desktop application, a simulation application (e.g., autonomous or semi-autonomous vehicle simulation), computer aided design (CAD) applications, virtual reality (VR) and/or augmented reality (AR) streaming applications, deep learning applications, and/or other application types. For example, the system 600 can be implemented to receive input indicating one or more features of output to be generated using a neural network model, provide the input to the model to cause the model to generate the output, and use the output for various operations including display or simulation operations.

In the system 600, for an application session, the client device(s) 604 may only receive input data in response to inputs to the input device(s) 626, transmit the input data to the application server(s) 602, receive encoded display data from the application server(s) 602, and display the display data on the display 624. As such, the more computationally intense computing and processing is offloaded to the application server(s) 602 (e.g., rendering—in particular ray or path tracing—for graphical output of the application session is executed by the GPU(s) of the application server(s) 602). In other words, the application session is streamed to the client device(s) 604 from the application server(s) 602, thereby reducing the requirements of the client device(s) 604 for graphics processing and rendering.

For example, with respect to an instantiation of an application session, a client device 604 may be displaying a frame of the application session on the display 624 based at least on receiving the display data from the application server(s) 602. The client device 604 may receive an input to one of the input device(s) 626 and generate input data in response. The client device 604 may transmit the input data to the application server(s) 602 via the communication interface 620 and over the network(s) 606 (e.g., the Internet), and the application server(s) 602 may receive the input data via the communication interface 618. The CPU(s) 608 may receive the input data, process the input data, and transmit data to the GPU(s) 610 that causes the GPU(s) 610 to generate a rendering of the application session. For example, the input data may be representative of a movement of a character of the user in a game session of a game application, firing a weapon, reloading, passing a ball, turning on a vehicle, etc. The rendering component 612 may render the application session (e.g., representative of the result of the input data) and the render capture component 614 may capture the rendering of the application session as display data (e.g., as image data capturing the rendered frame of the application session). The rendering of the application session may include ray or path-traced lighting and/or shadow effects, computed using one or more parallel processing units-such as GPUs, which may further employ the use of one or more dedicated hardware accelerators or processing cores to perform ray or path-tracing techniques—of the application server(s) 602. In some embodiments, one or more virtual machines (VMs)—e.g., including one or more virtual components, such as vGPUs, vCPUs, etc.—may be used by the application server(s) 602 to support the application sessions. The encoder 616 may then encode the display data to generate encoded display data and the encoded display data may be transmitted to the client device 604 over the network(s) 606 via the communication interface 618. The client device 604 may receive the encoded display data via the communication interface 620 and the decoder 622 may decode the encoded display data to generate the display data. The client device 604 may then display the display data via the display 624.

### Example Computing Device

FIG. 7 is a block diagram of an example computing device(s) 700 suitable for use in implementing some embodiments of the present disclosure. Computing device 700 may include an interconnect system 702 that directly or indirectly couples the following devices: memory 704, one or more central processing units (CPUs) 706, one or more graphics processing units (GPUs) 708, a communication interface 710, input/output (I/O) ports 712, input/output components 714, a power supply 716, one or more presentation components 718 (e.g., display(s)), and one or more logic units 720. In at least one embodiment, the computing device(s) 700 may comprise one or more virtual machines (VMs), and/or any of the components thereof may comprise virtual components (e.g., virtual hardware components). For non-limiting examples, one or more of the GPUs 708 may comprise one or more vGPUs, one or more of the CPUs 706 may comprise one or more vCPUs, and/or one or more of the logic units 720 may comprise one or more virtual logic units. As such, a computing device(s) 700 may include discrete components (e.g., a full GPU dedicated to the computing device 700), virtual components (e.g., a portion of a GPU dedicated to the computing device 700), or a combination thereof.

Although the various blocks of FIG. 7 are shown as connected via the interconnect system 702 with lines, this is not intended to be limiting and is for clarity only. For example, in some embodiments, a presentation component 718, such as a display device, may be considered an I/O component 714 (e.g., if the display is a touch screen). As another example, the CPUs 706 and/or GPUs 708 may include memory (e.g., the memory 704 may be representative of a storage device in addition to the memory of the GPUs 708, the CPUs 706, and/or other components). In other words, the computing device of FIG. 7 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 7.

The interconnect system 702 may represent one or more links or busses, such as an address bus, a data bus, a control bus, or a combination thereof. The interconnect system 702 may be arranged in various topologies, including but not limited to bus, star, ring, mesh, tree, or hybrid topologies. The interconnect system 702 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 706 may be directly connected to the memory 704. Further, the CPU 706 may be directly connected to the GPU 708. Where there is direct, or point-to-point connection between components, the interconnect system 702 may include a PCIe link to carry out the connection. In these examples, a PCI bus need not be included in the computing device 700.

The memory 704 may include any of a variety of computer-readable media. The computer-readable media may be any available media that may be accessed by the computing device 700. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 704 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 700. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 706 may be configured to execute at least some of the computer-readable instructions to control one or more components of the computing device 700 to perform one or more of the methods and/or processes described herein. The CPU(s) 706 may each include one or more cores (e.g., one, two, four, eight, twenty-eight, seventy-two, etc.) that are capable of handling a multitude of software threads simultaneously. The CPU(s) 706 may include any type of processor and may include different types of processors depending on the type of computing device 700 implemented (e.g., processors with fewer cores for mobile devices and processors with more cores for servers). For example, depending on the type of computing device 700, the processor may be an Advanced RISC Machines (ARM) processor implemented using Reduced Instruction Set Computing (RISC) or an x86 processor implemented using Complex Instruction Set Computing (CISC). The computing device 700 may include one or more CPUs 706 in addition to one or more microprocessors or supplementary co-processors, such as math co-processors.

In addition to or alternatively from the CPU(s) 706, the GPU(s) 708 may be configured to execute at least some of the computer-readable instructions to control one or more components of the computing device 700 to perform one or more of the methods and/or processes described herein. One or more of the GPU(s) 708 may be an integrated GPU (e.g., with one or more of the CPU(s) 706 and/or one or more of the GPU(s) 708 may be a discrete GPU. In embodiments, one or more of the GPU(s) 708 may be a coprocessor of one or more of the CPU(s) 706. The GPU(s) 708 may be used by the computing device 700 to render graphics (e.g., 3D graphics) or perform general purpose computations. For example, the GPU(s) 708 may be used for General-Purpose computing on GPUs (GPGPU). The GPU(s) 708 may include hundreds or thousands of cores that are capable of handling hundreds or thousands of software threads simultaneously. The GPU(s) 708 may generate pixel data for output images in response to rendering commands (e.g., rendering commands from the CPU(s) 706 received via a host interface). The GPU(s) 708 may include graphics memory, such as display memory, for storing pixel data or any other suitable data, such as GPGPU data. The display memory may be included as part of the memory 704. The GPU(s) 708 may include two or more GPUs operating in parallel (e.g., via a link). The link may directly connect the GPUs (e.g., using NVLINK) or may connect the GPUs through a switch (e.g., using NVSwitch). When combined together, each GPU 708 may generate pixel data or GPGPU data for different portions of an output or for different outputs (e.g., a first GPU for a first image and a second GPU for a second image). Each GPU 708 may include its own memory or may share memory with other GPUs.

In addition to or alternatively from the CPU(s) 706 and/or the GPU(s) 708, the logic unit(s) 720 may be configured to execute at least some of the computer-readable instructions to control one or more components of the computing device 700 to perform one or more of the methods and/or processes described herein. In embodiments, the CPU(s) 706, the GPU(s) 708, and/or the logic unit(s) 720 may discretely or jointly perform any combination of the methods, processes and/or portions thereof. One or more of the logic units 720 may be part of and/or integrated in one or more of the CPU(s) 706 and/or the GPU(s) 708 and/or one or more of the logic units 720 may be discrete components or otherwise external to the CPU(s) 706 and/or the GPU(s) 708. In embodiments, one or more of the logic units 720 may be a coprocessor of one or more of the CPU(s) 706 and/or one or more of the GPU(s) 708.

Examples of the logic unit(s) 720 include one or more processing cores and/or components thereof, such as Data Processing Units (DPUs), Tensor Cores (TCs), Tensor Processing Units (TPUs), Pixel Visual Cores (PVCs), Vision Processing Units (VPUs), Image Processing Units (IPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 710 may include one or more receivers, transmitters, and/or transceivers that allow the computing device 700 to communicate with other computing devices via an electronic communication network, including wired and/or wireless communications. The communication interface 710 may include components and functionality to allow communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 720 and/or communication interface 710 may include one or more data processing units (DPUs) to transmit data received over a network and/or through interconnect system 702 directly to (e.g., a memory of) one or more GPU(s) 708. In some embodiments, a plurality of computing devices 700 or components thereof, which may be similar or different to one another in various respects, can be communicatively coupled to transmit and receive data for performing various operations described herein, such as to facilitate latency reduction.

The I/O ports 712 may allow the computing device 700 to be logically coupled to other devices including the I/O components 714, the presentation component(s) 718, and/or other components, some of which may be built in to (e.g., integrated in) the computing device 700. Illustrative I/O components 714 include a microphone, mouse, keyboard, joystick, game pad, game controller, satellite dish, scanner, printer, wireless device, etc. The I/O components 714 may provide a natural user interface (NUI) that processes air gestures, voice, or other physiological inputs generated by a user. In some instances, inputs may be transmitted to an appropriate network element for further processing, such as to modify and register images. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 700. The computing device 700 may include depth cameras, such as stereoscopic camera systems, infrared camera systems, RGB camera systems, touchscreen technology, and combinations of these, for gesture detection and recognition. Additionally, the computing device 700 may include accelerometers or gyroscopes (e.g., as part of an inertia measurement unit (IMU)) that allow detection of motion. In some examples, the output of the accelerometers or gyroscopes may be used by the computing device 700 to render immersive augmented reality or virtual reality.

The power supply 716 may include a hard-wired power supply, a battery power supply, or a combination thereof. The power supply 716 may provide power to the computing device 700 to allow the components of the computing device 700 to operate.

The presentation component(s) 718 may include a display (e.g., a monitor, a touch screen, a television screen, a heads-up-display (HUD), other display types, or a combination thereof), speakers, and/or other presentation components. The presentation component(s) 718 may receive data from other components (e.g., the GPU(s) 708, the CPU(s) 706, DPUs, etc.), and output the data (e.g., as an image, video, sound, etc.).

### Example Data Center

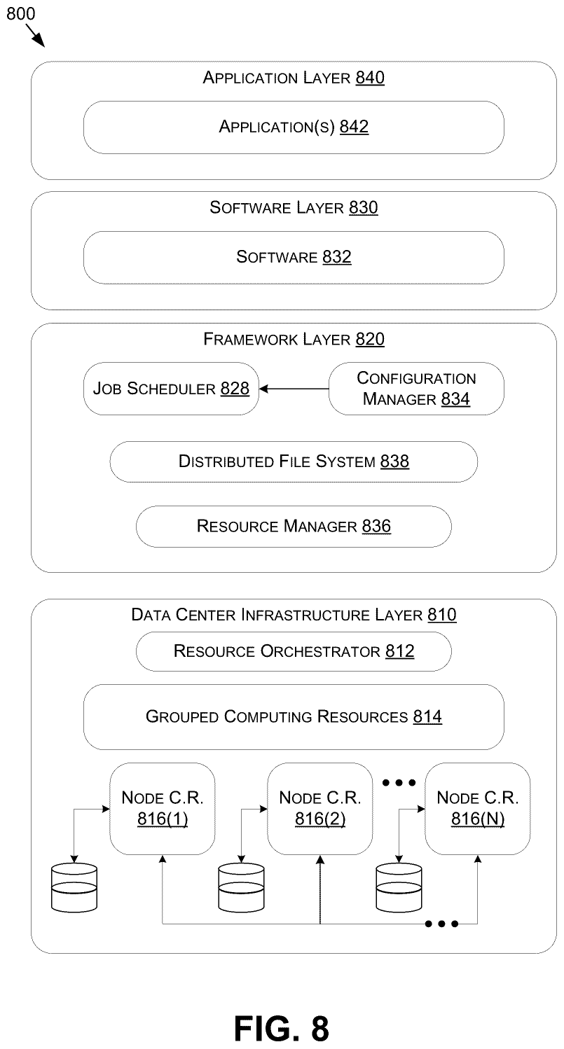

FIG. 8 illustrates an example data center 800 that may be used in at least one embodiments of the present disclosure, such as to implement the systems 100, 200, or in one or more examples of the data center 800. The data center 800 may include a data center infrastructure layer 810, a framework layer 820, a software layer 830, and/or an application layer 840.

As shown in FIG. 8, the data center infrastructure layer 810 may include a resource orchestrator 812, grouped computing resources 814, and node computing resources (“node C.R.s”) 816(1)-1316(N), where “N” represents any whole, positive integer. In at least one embodiment, node C.R.s 816(1)-1316(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 816(1)-1316(N) may correspond to a server having one or more of the above-mentioned computing resources. In addition, in some embodiments, the node C.R.s 816(1)-13161(N) may include one or more virtual components, such as vGPUs, vCPUs, and/or the like, and/or one or more of the node C.R.s 816(1)-1316(N) may correspond to a virtual machine (VM).

In at least one embodiment, grouped computing resources 814 may include separate groupings of node C.R.s 816 housed within one or more racks (not shown), or many racks housed in data centers at various geographical locations (also not shown). Separate groupings of node C.R.s 816 within grouped computing resources 814 may include grouped compute, network, memory or storage resources that may be configured or allocated to support one or more workloads. In at least one embodiment, several node C.R.s 816 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 812 may configure or otherwise control one or more node C.R.s 816(1)-1316(N) and/or grouped computing resources 814. In at least one embodiment, resource orchestrator 812 may include a software design infrastructure (SDI) management entity for the data center 800. The resource orchestrator 812 may include hardware, software, or some combination thereof.

In at least one embodiment, as shown in FIG. 8, framework layer 820 may include a job scheduler 828, a configuration manager 834, a resource manager 836, and/or a distributed file system 838. The framework layer 820 may include a framework to support software 832 of software layer 830 and/or one or more application(s) 842 of application layer 840. The software 832 or application(s) 842 may respectively include web-based service software or applications, such as those provided by Amazon Web Services, Google Cloud and Microsoft Azure. The framework layer 820 may be, but is not limited to, a type of free and open-source software web application framework such as Apache Spark™ (hereinafter “Spark”) that may utilize distributed file system 838 for large-scale data processing (e.g., “big data”). In at least one embodiment, job scheduler 828 may include a Spark driver to facilitate scheduling of workloads supported by various layers of data center 800. The configuration manager 834 may be capable of configuring different layers such as software layer 830 and framework layer 820 including Spark and distributed file system 838 for supporting large-scale data processing. The resource manager 836 may be capable of managing clustered or grouped computing resources mapped to or allocated for support of distributed file system 838 and job scheduler 828. In at least one embodiment, clustered or grouped computing resources may include grouped computing resource 814 at data center infrastructure layer 810. The resource manager 836 may coordinate with resource orchestrator 812 to manage these mapped or allocated computing resources.

In at least one embodiment, software 832 included in software layer 830 may include software used by at least portions of node C.R.s 816(1)-1316(N), grouped computing resources 814, and/or distributed file system 838 of framework layer 820. One or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-1316(N), grouped computing resources 814, and/or distributed file system 838 of framework layer 820. One or more types of applications may include, but are not limited to, any number of a genomics application, a cognitive compute, and a machine-learning application, including training or inferencing software, machine-learning framework software (e.g., PyTorch, TensorFlow, Caffe, etc.), and/or other machine-learning applications used in conjunction with one or more embodiments, such as to generate tokens to model agent actions, and/or to update/train transformer models (e.g., the transformer model 118, the transformer model 300) to generate simulated actions for agents in a scene (e.g., the scene 106).

In at least one embodiment, any of configuration manager 834, resource manager 836, and resource orchestrator 812 may implement any number and type of self-modifying actions based at least on any amount and type of data acquired in any technically feasible fashion. Self-modifying actions may relieve a data center operator of data center 800 from making possibly bad configuration decisions and possibly avoiding underutilized and/or poor performing portions of a data center.

The data center 800 may include tools, services, software or other resources to update/train one or more machine-learning models (e.g., the transformer model 118, the transformer model 300, etc.) or predict or infer information using one or more machine-learning models according to one or more embodiments described herein. For example, a machine-learning model(s) may be updated/trained by calculating weight parameters according to a neural network architecture using software and/or computing resources described above with respect to the data center 800. In at least one embodiment, trained or deployed machine-learning models corresponding to one or more neural networks may be used to infer or predict information using resources described above with respect to the data center 800 by using weight parameters calculated through one or more training techniques, such as but not limited to those described herein.

In at least one embodiment, the data center 800 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to update/train or perform inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 700 of FIG. 7—e.g., each device may include similar components, features, and/or functionality of the computing device(s) 700. In addition, where backend devices (e.g., servers, NAS, etc.) are implemented, the backend devices may be included as part of a data center 800, an example of which is described in more detail herein with respect to FIG. 8.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 700 described herein with respect to FIG. 7. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. A processor comprising:
one or more circuits to:
identify a plurality of trajectories in a dataset;
generate a plurality of actions based at least on the plurality of trajectories in the dataset; and
generate, based at least on the plurality of actions and at least one trajectory of the plurality of trajectories, a set of tokens representing actions to generate trajectories of one or more agents in a simulation.

2. The processor of claim 1, wherein the one or more circuits are to:
select a first action for the set of tokens from the plurality of actions; and
filter the plurality of actions based at least on the first action and a threshold distance.

3. The processor of claim 1, wherein each action in the plurality of actions comprises a change in position and a change in heading.

4. The processor of claim 1, wherein the one or more circuits are to:
generate a plurality of candidate sets of tokens based at least on the plurality of actions;
evaluate each of the plurality of candidate sets of tokens based at least on the at least one trajectory; and
select the set of tokens from the plurality of candidate sets of tokens based at least on the evaluation.

5. The processor of claim 4, wherein the one or more circuits are to evaluate each candidate set of the plurality of candidate sets of tokens by:
generating a tokenized trajectory based at least on the candidate set and the at least one trajectory; and
determining an error between the tokenized trajectory and the at least one trajectory.

6. The processor of claim 5, wherein the one or more circuits are to determine the error based at least on respective bounding boxes surrounding each of the tokenized trajectory and the at least one trajectory.

7. The processor of claim 1, wherein the one or more circuits are to update a transformer model using the set of tokens.

8. The processor of claim 7, wherein the one or more circuits are to update the transformer model further based at least on map data.

9. The processor of claim 1, wherein the processor is comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for 3D assets;
a system for performing deep learning operations;
a system implemented using an edge device;
a system implemented using a robot;
a system for performing conversational AI operations;
a system for performing generative AI operations;
a system for performing one or more operations using a large language model (LLM);
a system for performing one or more operations using a vision language model (VLM);
a system for generating synthetic data;
a system incorporating one or more virtual machines (VMs);
a system implemented at least partially in a data center; or
a system implemented at least partially using cloud computing resources.

10. A processor comprising:
one or more circuits to:
identify a plurality of trajectories in a dataset;
generate a plurality of tokenized trajectories based at least on the plurality of trajectories and a set of tokens representing actions to be performed at a given timestep along the plurality of trajectories; and
update a transformer model to generate a simulated action for a simulated agent based at least on the plurality of tokenized trajectories.

11. The processor of claim 10, wherein the one or more circuits are to update the transformer model based at least on map data.

12. The processor of claim 11, wherein the map data comprises one or more map objects.

13. The processor of claim 12, wherein the transformer model comprises an encoder-decoder architecture.

14. The processor of claim 10, wherein generating the plurality of tokenized trajectories comprises identifying a respective token from the set of tokens for each timestep of the plurality of trajectories.

15. The processor of claim 10, wherein the transformer model is updated to generate, in an output data structure, a respective simulated action for each of a plurality of simulated agents.

16. The processor of claim 10, wherein the transformer model is updated to receive an initial state of the simulated agent as input, the initial state comprising one or more of a length, a width, an initial position, an initial heading, or an object class of the simulated agent.

17. The processor of claim 16, wherein the object class comprises one of a pedestrian, a vehicle, or a cyclist.

18. A method, comprising:
identifying, using one or more processors, a plurality of trajectories in a dataset;
generating, using the one or more processors, a plurality of actions based at least on the plurality of trajectories in the dataset; and
generating, using the one or more processors, based at least on the plurality of actions and at least one trajectory of the plurality of trajectories, a set of tokens representing actions to generate trajectories of one or more agents in a simulation.

19. The method of claim 17, further comprising:
selecting, using the one or more processors, a first action for the set of tokens from the plurality of actions; and
filtering, using the one or more processors, the plurality of actions based at least on the first action and a threshold distance.

20. The method of claim 17, further comprising:
generating, using the one or more processors, a plurality of candidate sets of tokens based at least on the plurality of actions;
evaluating, using the one or more processors, each of the plurality of candidate sets of tokens based at least on the at least one trajectory; and
selecting, using the one or more processors, the set of tokens from the plurality of candidate sets of tokens based at least on the evaluation.
